(19) United States
(12) Patent Application Publication
(10) Pub. No.: US 2026/0206248 A1
(43) Pub. Date: Jul. 16, 2026

(54) NITRIDE-BASED SEMICONDUCTOR DEVICE

(71) Applicant: SEOUL VIOSYS CO., LTD., Ansan-si (KR)

(72) Inventors: YongHyun BAEK, Ansan-si (KR); EunJin KIM, Ansan-si (KR); HyeonSu YU, Ansan-si (KR)

(73) Assignee: SEOUL VIOSYS CO., LTD., Ansan-si (KR)

(21) Appl. No.: 19/382,337

(22) Filed: Nov. 7, 2025

Related U.S. Application Data
(60) Provisional application No. 63/720,944, filed on Nov. 15, 2024.

(51) Int. Cl. H10D 30/47; H10D 62/60; H10D 62/824

(52) U.S. Cl. CPC H10D 30/475; H10D 62/60; H10D 62/824

(57) ABSTRACT

According to one aspect of the present disclosure, there may be provided a nitride-based semiconductor device, including: a substrate; a nucleation layer stacked on the substrate; a buffer layer stacked on the nucleation layer; a channel layer stacked on the buffer layer and configured to provide an electron transport path; and a barrier layer stacked on the channel layer to form the electron transport path, wherein the barrier layer includes nitrogen, gallium, aluminum, and oxygen, and wherein a concentration of oxygen at a top of the barrier layer is less than a concentration of aluminum at the top of the barrier layer.

This disclosure relates to the development of Gallium Nitride (GaN)-based 150 nm process technology and applied systems (3.5 km class fixed drone detection radar) (No. 9991008828, 22-CM-TN-15), a research project performed with support from the Civil-Military Cooperation Promotion Agency of the Agency for Defense Development, funded by the Ministry of Trade. Industry and Energy and the Defense Acquisition Program Administration (Government) in 2022.

### TECHNICAL FIELD

The present disclosure relates to a nitride-based semiconductor device.

### BACKGROUND OF INVENTION

Due to the development of information and communication technology, the need for high-voltage semiconductor devices operating in high-speed switching or high-voltage environments is increasing. Accordingly, recently emerged gallium nitride-based semiconductor devices are capable of high-speed switching operations compared to conventional silicon-based devices, making them suitable for ultra-high-speed signal processing, and also have the advantage of being applicable in high-voltage environments due to the material's inherent high breakdown voltage characteristics.

In the case of a high-electron-mobility transistor (HEMT), a semiconductor device using gallium nitride, by using a 2-dimensional electron gas (2DEG) formed at an interface between heterogeneous materials, electron mobility may be increased, which is advantageous for high-speed signal transmission.

Meanwhile, a semiconductor device is manufactured by stacking different materials on a substrate. For example, a buffer layer, a channel layer, a barrier layer, and the like may be stacked on a substrate, and each layer may include a different material. In semiconductor devices, there is a problem that the substrate may warp or be deformed, and cracks may occur due to different lattice constants and thermal expansion coefficients between the materials constituting each layer stacked on the substrate. If the substrate warps or is deformed, the substrate may not firmly support the materials on top, and if the warping or deformation is severe, there is a problem that the substrate may break.

### CONTENTS OF INVENTION

### Problems to be Solved by Invention

An exemplary embodiment of the present disclosure provides a nitride-based semiconductor device in which defect formation may be minimized.

### Means for Solving Problems

In accordance with one aspect of the present disclosure, there may be provided a nitride-based semiconductor device, including: a substrate; a nucleation layer stacked on the substrate; a buffer layer stacked on the nucleation layer; a channel layer stacked on the buffer layer and configured to provide an electron transport path; and a barrier layer stacked on the channel layer to form the electron transport path, wherein the barrier layer includes nitrogen, gallium, aluminum, and oxygen, and wherein a concentration of oxygen at a top of the barrier layer is less than a concentration of aluminum at the top of the barrier layer.

Further, there may be provided the nitride-based semiconductor device in which an average of a concentration of nitrogen in the barrier layer is greater than an average of a concentration of each of gallium, aluminum, and oxygen in the barrier layer.

Further, there may be provided the nitride-based semiconductor device in which an average of a concentration of gallium in the barrier layer is greater than an average of a concentration of each of aluminum and oxygen in the barrier layer.

Further, there may be provided the nitride-based semiconductor device in which an average of a concentration of aluminum in the barrier layer is greater than an average of a concentration of oxygen in the barrier layer.

Further, there may be provided the nitride-based semiconductor device in which the channel layer comprises gallium and nitrogen, and an average of a concentration of nitrogen in the barrier layer is lower than an average of a concentration of nitrogen in the channel layer.

Further, there may be provided the nitride-based semiconductor device in which an average of a concentration of gallium in the barrier layer is lower than an average of a concentration of gallium in the channel layer.

Further, there may be provided the nitride-based semiconductor device in which the barrier layer comprises a transition region, a first region disposed on the transition region, and a second region and a third region disposed on the first region, the transition region is stacked on the channel layer, and an average of a concentration of gallium in the transition region is greater than an average of a concentration of gallium in each of the third region, the second region, and the first region.

Further, there may be provided the nitride-based semiconductor device in which the concentration of gallium in the transition region decreases toward the first region.

Further, there may be provided the nitride-based semiconductor device in which a concentration of aluminum in the transition region increases toward the first region.

Further, there may be provided the nitride-based semiconductor device in which a concentration of gallium at a top of the first region and a concentration of gallium at a bottom of the first region are less than a concentration of gallium at a central portion of the first region.

Further, there may be provided the nitride-based semiconductor device in which the concentration of gallium in the second region increases toward the third region.

Further, there may be provided the nitride-based semiconductor device in which a concentration of aluminum in the second region decreases toward the third region.

Further, there may be provided the nitride-based semiconductor device in which the concentration of gallium in the third region decreases toward a top of the third region.

Further, there may be provided the nitride-based semiconductor device in which a concentration of oxygen in the third region increases toward a top of the third region.

Further, there may be provided the nitride-based semiconductor device in which a concentration of aluminum in the third region decreases toward a top of the third region.

Further, there may be provided the nitride-based semiconductor device in which a concentration of gallium at the top of the second region is higher than the concentration of gallium in the first region, and the concentration of gallium at the top of the second region is less than a concentration of gallium at a bottom of the transition region.

Further, there may be provided the nitride-based semiconductor device in which an average of a concentration of oxygen in the second region is lower than an average of a concentration of oxygen in the third region.

Further, there may be provided the nitride-based semiconductor device in which a concentration of gallium at the top of the second region is less than a concentration of gallium at the bottom of the transition region.

Further, there may be provided the nitride-based semiconductor device including: a substrate; a nucleation layer stacked on the substrate; a buffer layer stacked on the nucleation layer; a channel layer stacked on the buffer layer to provide an electron transport path; and a barrier layer including nitrogen, gallium, aluminum, and oxygen, stacked on the channel layer, and configured to form a 2-dimensional electron gas, wherein the barrier layer includes a transition region a first region disposed on the transition region, and a second region and a third region disposed on the first region, wherein a concentration of gallium in the second region increases toward the third region, wherein a concentration of aluminum in the second region decreases toward the third region, and wherein an absolute value of a concentration change rate of gallium in the second region is greater than an absolute value of a concentration change rate of aluminum in the second region.

Further, there may be provided the nitride-based semiconductor device including: a substrate; a nucleation layer stacked on the substrate; a buffer layer stacked on the nucleation layer; a channel layer stacked on the buffer layer to provide an electron transport path; and a barrier layer including nitrogen, gallium, aluminum, and oxygen, stacked on the channel layer, and configured to form a 2-dimensional electron gas, wherein the barrier layer includes a transition region, a first region disposed on the transition region, and a second region and a third region disposed on the first region, and wherein a concentration of gallium at a central portion of the first region is less than a concentration of gallium at any one of a top and a bottom of the first region.

### Effects of Invention

An embodiment of the present disclosure minimizes the formation of defects (cracks) in the nitride-based semiconductor device using the buffer layer, the channel layer, and the barrier layer.

Furthermore, an embodiment of the present disclosure suppresses the generation of leakage current in the nitride-based semiconductor device using the buffer layer, the channel layer, and the barrier layer.

Furthermore, an embodiment of the present disclosure reduces signal distortion in the nitride-based semiconductor device using the buffer layer, the channel layer, and the barrier layer.

### BRIEF DESCRIPTION OF DRAWINGS

FIG. 1 is a diagram illustrating a nitride-based semiconductor device according to an embodiment.

FIG. 2 is an SEM photograph of a channel layer and a barrier layer of a nitride-based semiconductor device according to an embodiment.

FIG. 3 is a diagram illustrating a transition region, a first region, a second region, and a third region of a barrier layer of the nitride-based semiconductor device of FIG. 1.

FIG. 4 is a graph illustrating a first example of the concentrations of gallium, nitrogen, aluminum, and oxygen included in the barrier layer of the nitride-based semiconductor device of FIG. 3.

FIG. 5 is a graph illustrating a second example of the concentrations of gallium, nitrogen, aluminum, and oxygen included in the barrier layer of the nitride-based semiconductor device of FIG. 3.

FIG. 6 is a graph illustrating a third example of the concentrations of gallium, nitrogen, aluminum, and oxygen included in the barrier layer of the nitride-based semiconductor device of FIG. 3.

FIG. 7 is a diagram illustrating a first electrode, a second electrode, and a third electrode disposed on an upper portion of a nitride-based semiconductor device according to an embodiment of the present disclosure.

### SPECIFIC CONTENTS FOR EMBODYING INVENTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a nitride-based semiconductor device 1 according to an embodiment will be described.

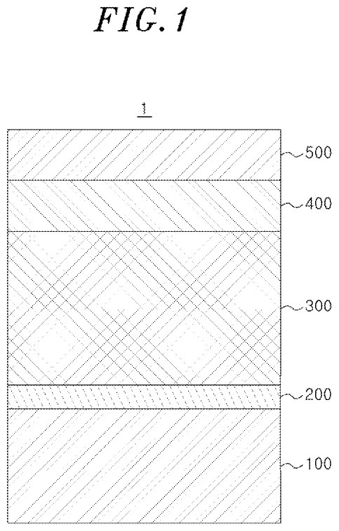

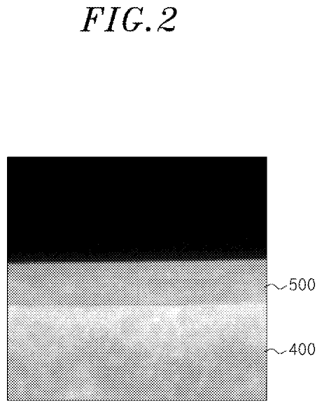

Referring to FIG. 1 and FIG. 2, a nitride-based semiconductor device 1 according to the embodiment of the present disclosure may be used as a component of an electronic circuit or the like by utilizing the electrical conduction characteristics of a semiconductor. The nitride-based semiconductor device 1 may include a substrate 100, a nucleation layer 200, a buffer layer 300, a channel layer 400, and a barrier layer 500.

The substrate 100 may support one or more of the nucleation layer 200, the buffer layer 300, the channel layer 400, and the barrier layer 500. Such a substrate 100 may be N-type or P-type and may include various materials. For example, the substrate 100 may be one of an insulating substrate, a sapphire substrate, a GaN substrate, a SIC substrate, and a Si substrate. Furthermore, the thickness of the substrate 100 may be 300 μm to 700 μm. In addition, various types of substrates 100 may be applicable to the nitride-based semiconductor device 1 according to the embodiment of the present disclosure.

The nucleation layer 200 may be stacked on the substrate 100. The nucleation layer 200 may be used to grow a nitride-based semiconductor material. In other words, the nucleation layer 200 may be disposed on the substrate 100 to grow one or more of the buffer layer 300, the channel layer 400, and the barrier layer 500. The nucleation layer 200 may serve to minimize lattice mismatch between the substrate 100 and the buffer layer 300, relieve stress, and reduce defect density. Furthermore, the nucleation layer 200 may reduce thermal stress between the substrate 100 and the buffer layer 300 to increase the stability of the device. Furthermore, the nucleation layer 200 may minimize the surface roughness of the substrate 100. Furthermore, since the nucleation layer 200 may serve to grow a layer grown from the substrate 100 in an appropriate crystal direction, the electrical and optical characteristics of the nitride-based semiconductor device 1 may be enhanced. The nucleation layer 200 may have a thickness of 100 nm or less.

The buffer layer 300 may be stacked on the nucleation layer 200. This buffer layer 300 may be a layer including GaN doped with C or Fe. Furthermore, the buffer layer 300 may be a semi-insulating GaN layer. The concentration of Fe in the buffer layer 300 may be group III-V at % to 10¹⁹ at %. The concentration of C or Fe in the buffer layer 300 may decrease to 10¹⁶ at % to 10¹⁷ at % toward the channel layer 400. If the concentration of C or Fe in the buffer layer 300 decreases toward the channel layer 400, defect formation may be minimized. The concentration of C or Fe in the buffer layer 300 may increase to 2E16 to 3E19 atoms/cm³ as the distance from the channel layer 400 increases. If the concentration of C or Fe in the buffer layer 300 increases as the distance from the channel layer 400 increases, the device 1 may secure semi-insulating characteristics. Furthermore, since the buffer layer 300 may have semi-insulating characteristics, the buffer layer 300 may serve to insulate the substrate 100 while suppressing leakage current. In addition, the buffer layer 300 may suppress current leakage while allowing a small amount of current, thereby reducing signal distortion in high-frequency devices. The buffer layer 300 may include a region of 500 nm or more having the concentration of C or Fe maintained substantially constant. Therefore, deviation of resistance may be prevented to stably maintain electrical characteristics.

A concentration ratio of C or Fe at an interface between the buffer layer 300 and the channel layer 400 may be greater than a concentration ratio of C or Fe at an interface between the buffer layer 300 and the nucleation layer 200. Therefore, a higher response speed may be implemented. Here, the concentration ratio may be the absolute value of the maximum concentration of C or the maximum concentration of Fe at the interface divided by the minimum concentration of C or the minimum concentration of Fe.

The buffer layer 300 may be thicker than the channel layer 400 and the barrier layer 500. The thickness of the buffer layer 300 may be formed to be 5 μm or less.

The buffer layer 300 may include a first region having a relatively high doping concentration and a second region having a relatively low doping concentration. A first region of the buffer layer 300 may be disposed adjacent to the channel layer 400, and a second region of the buffer layer 300 may be disposed adjacent to the nucleation layer 200. The difference in doping concentration between the first region and the second region of the buffer layer 300 may be 100 times or more. Furthermore, the thickness of the second region of the buffer layer 300 may be greater than the thickness of the first region of the buffer layer 300, but less than 1.7 times the thickness of the first region of the buffer layer 300. Therefore, the first region of the buffer layer 300 may be formed on the second region of the buffer layer 300, which has improved thin film quality, to prevent dopants in the first region from acting as defects.

The oxygen concentration of the buffer layer 300 may be lower than the oxygen concentration of the nucleation layer 200. Therefore, preventing the dopant of the buffer layer 300 from being deactivated by combining with oxygen is possible. The oxygen concentration of the nucleation layer 200 may be 1E19 atoms % cm³ or more, and the oxygen concentration of the buffer layer 300 may be less than 1E19 atoms/cm³.

The channel layer 400 may be a region where the flow of electrons and current occurs. The channel layer 400 may include a group III-V compound. For example, the channel layer 400 may include a GaN-based material. The channel layer 400 may be an undoped layer or a layer doped with unintentional impurities, but the channel layer 400 may also be a layer doped with one of C, Fe, Mg, and Mn dopants. The channel layer 400 may be disposed on the buffer layer 300. The channel layer 400 may be formed by one of metal-organic chemical vapor deposition (MOCVD), molecular beam epitaxy (MBE), and hydride vapor phase epitaxy (HVPE). The thickness of the channel layer 400 may be 2 μm or less. The channel layer 400 may be 0.005 to 0.02 times the thickness of the buffer layer 300. Therefore, the distance between an electrode, to be described later, and the buffer layer 300 may be formed to be short, so channel formation may be easy.

Furthermore, an electron transport channel, through which electrons move, may be formed in the channel layer 400. The electron transport channel may be formed on top of the channel layer 400, adjacent to the barrier layer 500. For example, a 2-dimensional electron gas (2DEG) may be formed as an electron transport channel on top of the channel layer 400.

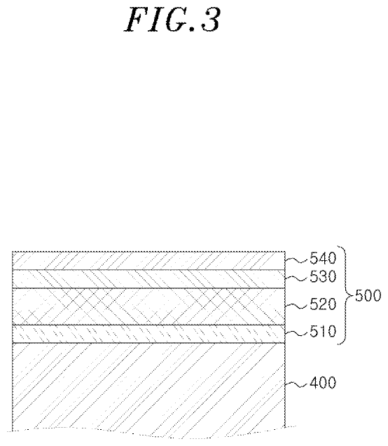

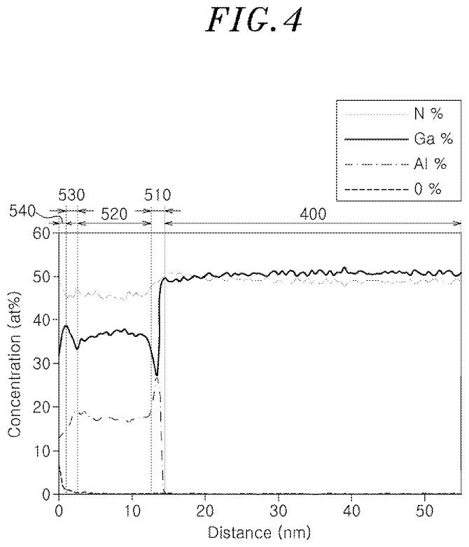

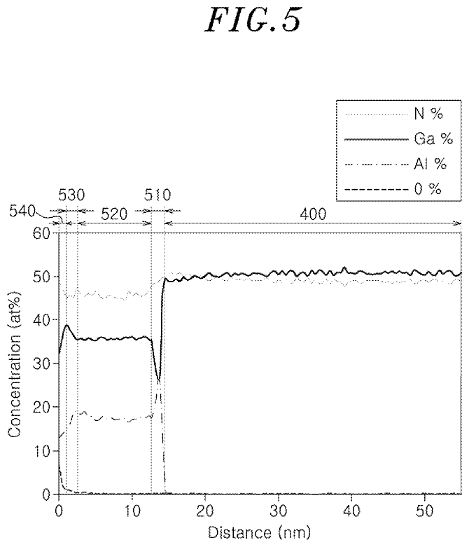

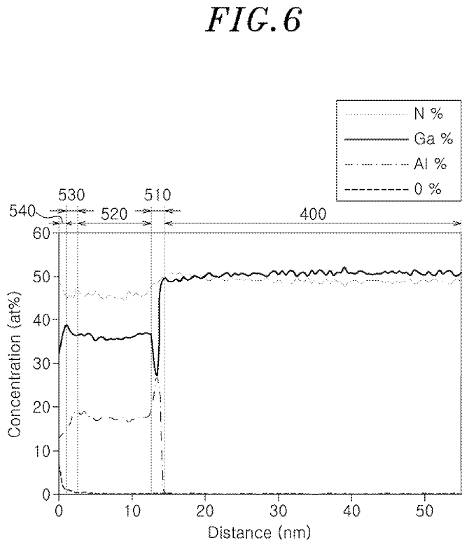

Referring further to FIG. 3 to FIG. 6, the barrier layer 500 may be a layer stacked on the channel layer 400 inducing an electron transport channel in the channel layer 400. The electron transport channel may be formed in the channel layer 400 below the interface between the channel layer 400 and the barrier layer 500. The barrier layer 500 may include a material having different polarization characteristics, bandgap energy, and lattice constant from the channel layer 400. Furthermore, the barrier layer 500 may include a material having a polarization and a bandgap energy greater than those of the channel layer 400. The barrier layer 500 may have a single-layer or multi-layer structure including one or more materials selected from nitrides including one of aluminum (Al), gallium (Ga), nitrogen (N), indium (In), boron (B), and oxygen (O). For example, the barrier layer 500 may include one or more of various materials including AlGaN, AlInN, InGaN, AlN, AlInGaN, and the like. The barrier layer 500 may be an undoped layer or a layer doped with certain impurities. The barrier layer 500 may be formed by one of metal-organic chemical vapor deposition (MOCVD), molecular beam epitaxy (MBE), and hydride vapor phase epitaxy (HVPE). The thickness of the barrier layer 500 may be 10 nm to 40 nm.

Furthermore, the concentrations of nitrogen, gallium, aluminum, and oxygen in the barrier layer 500 may increase or decrease toward a top of the barrier layer 500. Hereinafter, an average of each of nitrogen, gallium, aluminum, and oxygen may be an average of the concentrations of nitrogen, gallium, aluminum, and oxygen varying in a stacking direction. A bottom of the barrier layer 500 may be a point where the concentration of gallium is relatively low. For example, the difference in gallium concentration between the channel layer 400 and the barrier layer 500 may be 20% or more. Therefore, a channel may be easily formed.

An average of the concentration of nitrogen in the barrier layer 500 may be formed to be greater than an average of the concentration of each of gallium, aluminum, and oxygen in the barrier layer 500. The average of the concentration of nitrogen in the barrier layer 500 may be lower than an average of the concentration of nitrogen in the channel layer 400. The concentration of nitrogen in the barrier layer 500 may be 44 at % or more and 50 at % or less.

An average of the concentration of gallium in the barrier layer 500 may be formed to be greater than an average of the concentration of each of aluminum and oxygen in the barrier layer 500. Furthermore, the average of the concentration of gallium in the barrier layer 500 may be lower than an average of the concentration of gallium in the channel layer 400. For example, the concentration of gallium may be 30 at % or more and less than 50 at %.

An average of the concentration of aluminum in the barrier layer 500 may be formed to be greater than an average of the concentration of oxygen in the barrier layer 500. For example, the concentration of aluminum may be 0.1 at % or more and less than 20 at %. Furthermore, the concentration of oxygen may be 0.1 at % or more and 8 at % or less.

Furthermore, the barrier layer 500 may include a transition region 510, a first region 520, a second region 530, and a third region 540.

The transition region 510 may be stacked on the channel layer 400. The transition region 510 may be a region transitioning from the channel layer 400 to the barrier layer 500. The concentration of one or more of nitrogen, gallium, aluminum, and oxygen in the transition region 510 may vary more than in the first region 520, the second region 530, and the third region 540. An average of the concentration of gallium in the transition region 510 may be formed to be greater than an average of the concentration of gallium in each of the first region 520, the second region 530, and the third region 540. For example, the concentration of gallium in the transition region 510 may be 34 at % or more and less than 50 at %. Alternatively, the concentration of gallium in the transition region 510 may be 25 at % or more and less than 50 at %. The concentration of gallium in the transition region 510 may decrease toward the first region 520. The concentration of gallium in the transition region 510 may also increase toward the first region 520. The concentration of gallium at the bottom of the transition region 510 may be substantially the same as the concentration of gallium at the top of the channel layer 400. The concentration of gallium at a top of the transition region 510 may be continuous with the concentration of gallium at a bottom of the first region 520, and may be the same as the concentration of gallium at the bottom of the first region 520. An absolute value of the change rate of gallium in the transition region 510 may be formed to be greater than an absolute value of the change rate of nitrogen in the transition region 510. A valley in the concentration of gallium in the barrier layer 500 may be formed in the transition region 510. The lowest concentration of gallium in the barrier layer 500 may be formed in the transition region 510.

An average of the concentration of nitrogen in the transition region 510 may be formed to be greater than an average of the concentration of nitrogen in each of the first region 520, the second region 530, and the third region 540. For example, the concentration of nitrogen in the transition region 510 may be 45 at % or more and 50 at % or less. The concentration of nitrogen in the transition region 510 may decrease toward the first region 520. Furthermore, the concentration of nitrogen at the bottom of the transition region 510 may be the same as the concentration of nitrogen at the top of the channel layer 400. Furthermore, the concentration of nitrogen at the top of the transition region 510 may be the same as the concentration of nitrogen at the bottom of the first region 520. A peak in the concentration of nitrogen in the barrier layer 500 may be formed in the transition region 510.

A maximum value of the concentration of aluminum in the transition region 510 may be greater than the concentration of aluminum in each of the first region 520, the second region 530, and the third region 540. Therefore, by forming a high energy barrier and preventing a channel path from diffusing to other regions, a shorter channel path is formed, and thereby a response speed may be improved. The concentration of aluminum in the transition region 510 may increase and then decrease toward the first region 520. The concentration of aluminum at the top of the transition region 510 may be the same as the concentration of aluminum at the bottom of the first region 520. An absolute value of the change rate of aluminum in the transition region 510 may be formed to be greater than an absolute value of the change rate of nitrogen in the transition region 510. Here, the change rate may be the difference between the maximum value and the minimum value of the material in the corresponding region.

An average of the concentration of oxygen in the transition region 510 may be formed to be less than an average of the concentration of oxygen in each of the first region 520, the second region 530, and the third region 540. For example, the concentration of oxygen in the transition region 510 may be 0.1 at % or more and 0.2 at % or less. Here, the oxygen concentration may be determined by atom probe tomography (APT). By maintaining a low oxygen concentration, oxidation of the semiconductor layer may be prevented.

The first region 520 may be stacked on the transition region 510. The thickness of the first region 520 may be formed to be greater than the thickness of each of the transition region 510, the second region 530, and the third region 540. The concentration of gallium in the first region 520 may be formed according to the following examples.

As a first example, the difference between the concentration of gallium at the top of the first region 520 and the concentration of gallium at the bottom of the first region 520 may be within 5 at %. In other words, the concentration of gallium in the first region 520 may increase from the bottom of the first region 520 to a central portion of the first region 520, and may decrease from the central portion of the first region 520 to the top of the first region 520. The concentration of gallium in the first region 520 may be formed to be 32 at % or more and 38 at % or less.

As a second example, the concentration of gallium at the top of the first region 520, the concentration of gallium at the bottom of the first region 520, and the concentration of gallium at the central portion of the first region 520 may be formed to be substantially the same. In other words, the concentration of gallium in the first region 520 may be maintained substantially constant from the bottom of the first region 520 to the top of the first region 520. The difference in gallium concentration in the first region 520 may be within 3 at %. The concentration of gallium in the first region 520 may be formed to be 34 at % or more and 36 at % or less. Therefore, lattice defects may be reduced, so gate leakage current is reduced, and frequency characteristics may be improved.

As a third example, the concentration of gallium at the top of the first region 520 and the concentration of gallium at the bottom of the first region 520 may be formed to be higher than the concentration of gallium at the central portion of the first region 520. In other words, the concentration of gallium in the first region 520 may decrease from the bottom of the first region 520 to the central portion of the first region 520, and may increase from the central portion of the first region 520 to the top of the first region 520. The concentration of gallium in the first region 520 may be formed to be 34 at % or more and less than 38 at %.

The concentration of gallium at the bottom of the first region 520 may be the same as the concentration of gallium at the top of the transition region 510. The concentration of gallium at the top of the first region 520 may be the same as the concentration of gallium at a bottom of the second region 530.

The concentration of nitrogen in the first region 520 may repeatedly increase and decrease or be maintained constant toward the second region 530. The concentration of nitrogen in the first region 520 may be formed to be 43 at % or more and less than 48 at %. The concentration of nitrogen at the bottom of the first region 520 may be the same as the concentration of nitrogen at the top of the transition region 510. Furthermore, the concentration of nitrogen at the top of the first region 520 may be the same as the concentration of nitrogen at the bottom of the second region 530.

The concentration of aluminum in the first region 520 may repeatedly increase and decrease or be maintained constant toward the second region 530. An average of the concentration of aluminum in the first region 520 may be formed to be greater than an average of the concentration of aluminum in each of the transition region 510, the second region 530, and the third region 540. Here, the average may mean a median value between the maximum value and the minimum value of the material in the corresponding region. For example, the concentration of aluminum in the first region 520 may be formed to be 16 at % or more and less than 20 at %. The concentration of aluminum at the top of the first region 520 may be the same as the concentration of aluminum at the bottom of the second region 530. The concentration of aluminum at the bottom of the first region 520 may be the same as the concentration of aluminum at a bottom of the transition region 510. A peak in the aluminum concentration of the barrier layer 500 may be formed in the transition region 510.

The concentration of oxygen at the top of the first region 520 may be formed to be higher than the concentration of oxygen at the bottom of the first region 520. The concentration of oxygen at the top of the first region 520 may be the same as the concentration of oxygen at the bottom of the second region 530. The concentration of oxygen at the bottom of the first region 520 may be the same as the concentration of oxygen at the top of the transition region 510. For example, the concentration of oxygen in the first region 520 may be 0.1 at % or more and 0.4 at % or less. Here, the oxygen concentration may be determined by atom probe tomography (APT). By maintaining a low oxygen concentration, oxidation of the transition region 510 may be prevented.

The second region 530 may be stacked on the first region 520. The concentration of gallium in the second region 530 may increase toward the third region 540. For example, the concentration of gallium in the second region 530 may be formed to be 33 at % or more and less than 40 at %. The concentration of gallium at a bottom of the second region 530 may be the same as the concentration of gallium at the top of the first region 520. Furthermore, the concentration of gallium at a top of the second region 530 may be the same as the concentration of gallium at a bottom of the third region 540. Furthermore, the concentration of gallium at the top of the second region 530 may be higher than the concentration of gallium in the first region 520. The concentration of gallium at the top of the second region 530 may be less than the concentration of gallium at the bottom of the transition region 510 and greater than the concentration of gallium at the top of the transition region 510. Furthermore, an absolute value of the change rate of the concentration of gallium in the second region 530 may be formed to be greater than an absolute value of the change rate of the concentration of aluminum in the second region 530.

The concentration of nitrogen at the bottom of the second region 530 may be less than the concentration of nitrogen at the top of the second region 530. In other words, the concentration of nitrogen in the second region 530 may decrease in at least a portion toward the third region 540. For example, the concentration of nitrogen in the second region 530 may be 44 at % or more and 50 at % or less. Furthermore, the concentration of nitrogen at the bottom of the second region 530 may be the same as the concentration of nitrogen at the top of the first region 520.

The concentration of nitrogen at the top of the second region 530 may be the same as the concentration of nitrogen at the bottom of the third region 540. The concentration of aluminum in the second region 530 may decrease toward the third region 540. The change rate of the concentration of aluminum in the second region 530 may be greater than the change rate of the concentration of aluminum in the third region 540. Furthermore, an absolute value of the change rate for the concentration of aluminum in the second region 530 may be less than an absolute value of the change rate for the concentration of aluminum in the transition region 510. The concentration of aluminum at the bottom of the second region 530 may be the same as the concentration of aluminum at the top of the first region 520. The concentration of aluminum at the top of the second region 530 may be the same as the concentration of aluminum at the bottom of the third region 540. For example, the concentration of aluminum in the second region 530 may be formed to be 15 at % or more and less than 20 at %.

The concentration of oxygen in the second region 530 may increase toward the third region 540. An average of the concentration of oxygen in the second region 530 may be lower than an average of the concentration of oxygen in the third region 540. The change rate of the concentration of oxygen in the second region 530 may be less than the change rate of the concentration of oxygen in the third region 540. The concentration of oxygen at the bottom of the second region 530 may be the same as the concentration of oxygen at the top of the first region 520. The concentration of oxygen at the top of the second region 530 may be the same as the concentration of oxygen at the bottom of the third region 540. For example, the oxygen concentration of the second region 530 may be 0.2 at % or more and 1 at % or less. Here, the oxygen concentration may be determined by atom probe tomography (APT).

The third region 540 may be stacked on the second region 530. A top of the third region 540 may be a top of the barrier layer 500. The concentration of gallium in the third region 540 may decrease toward the top of the third region 540. An absolute value of the change rate of the concentration of gallium in the third region 540 may be greater than an absolute value of the change rate of the concentration of aluminum in the third region 540. An absolute value of the change rate of the concentration of gallium in the third region 540 may be greater than an absolute value of the change rate of the concentration of nitrogen in the third region 540. The concentration of gallium at the top of the third region 540 may be less than the concentration of gallium in the first region 520 and the concentration of gallium in the transition region 510. For example, the concentration of gallium in the third region 540 may be 31 at % or more and less than 40 at %.

The concentration of nitrogen in the third region 540 may increase toward the top of the third region 540. The concentration of nitrogen at the top of the third region 540 may be greater than the concentration of nitrogen in the second region 530 and the first region 520, and less than the concentration of nitrogen at the bottom of the transition region 510. The concentration of nitrogen at a bottom of the third region 540 may be the same as the concentration of nitrogen at the top of the second region 530. For example, the concentration of nitrogen in the third region 540 may be 45 at % or more and 49 at % or less.

The concentration of aluminum in the third region 540 may decrease toward the top of the third region 540. The concentration of aluminum at the top of the third region 540 may be less than the concentration of aluminum in the second region 530 and the first region 520, and greater than the concentration of aluminum at the bottom of the transition region 510. The concentration of aluminum at the bottom of the third region 540 may be the same as the concentration of aluminum at the top of the second region 530. An absolute value of the change rate of the concentration of aluminum in the third region 540 may be less than an absolute value of the change rate of the concentration of oxygen in the third region 540 and an absolute value of the change rate of the concentration of gallium in the third region 540. For example, the concentration of aluminum in the third region 540 may be 12 at % or more and 16 at % or less.

The concentration of oxygen in the third region 540 may increase toward the top of the third region 540. The concentration of oxygen at the top of the third region 540 may be greater than the concentration of oxygen in the second region 530, the first region 520, and the transition region 510. The concentration of oxygen at the bottom of the third region 540 may be the same as the concentration of oxygen at the top of the second region 530. For example, the concentration of oxygen in the third region 540 may be 1 at % or more and 8 at % or less.

The bandgap energy of the third region 540 may decrease toward the top of the third region 540. The bandgap energy of the third region 540 may vary within a range of 3.96 eV to 4.52 eV. Here, the bandgap energy may be calculated as Eg(AlxGa₍₁₋ₓ₎N)=xEg(AlN)+(1−x)Eg(GaN), (0≤x≤1, Eg(AlN)=6.2, Eg(GaN)=3.4). The difference between the bandgap energy at a top surface of the third region 540 (E1) and the bandgap energy in a region where the third region 540 contacts the second region 530 (E2) may be within 0.6 eV. Therefore, the 2DEG formation speed may be increased by making the bandgap energy difference within 0.6 eV.

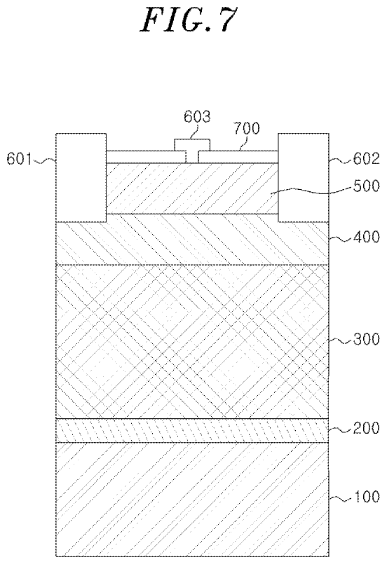

Referring to FIG. 7, the nitride-based semiconductor device 1 may include a first electrode 601, a second electrode 602, and a third electrode 603. The first electrode 601, the second electrode 602, and the third electrode 603 may be disposed on an upper portion of the nitride-based semiconductor device 1 and may be electrically connected to the nitride-based semiconductor device 1. The first electrode 601 may be connected to the barrier layer 500 and the channel layer 400. The third electrode 603 may be connected to the barrier layer 500. A bottom surface of the first electrode 601 and the second electrode 602 may be located lower than a bottom surface of the third electrode 603. The bottom surface of the first electrode 601 and the second electrode 602 may be disposed below a bottom surface of the barrier layer 500 and below a top surface of the channel layer 400. Furthermore, the third electrode 603 may be connected to the top side of the barrier layer 500. The first electrode 601 may function as a source electrode, the second electrode 602 as a drain electrode, and the third electrode 603 as a gate electrode.

Furthermore, the nitride-based semiconductor device 1 may further include an insulating layer 700. The insulating layer 700 may be disposed on the upper portion of the nitride-based semiconductor device 1. The insulating layer 700 may be a material with electrical insulating properties, such as SixOy or SixNy. The insulating layer 700 may include an opening exposing a top surface of the semiconductor device 1. A top surface of the barrier layer 500 may be exposed by an opening in the insulating layer 700. Therefore, the third electrode 603 may be electrically connected to the top surface of the nitride-based semiconductor device 1 exposed through the opening. The top surface of the barrier layer 500 and the third electrode 603 may be connected. A width of a bottom surface of the third electrode 603 may be less than a width of a top surface of the third electrode 603. Therefore, the response speed may be improved. The width of the bottom surface of the third electrode 603 may be less than the thickness of the barrier layer 500. Furthermore, the width of the bottom surface of the third electrode 603 may be less than the thickness of the transition region 510. Furthermore, the width of the bottom surface of the third electrode 603 may be greater than the thickness of the first region 520 of the barrier layer 500. Therefore, the distance between the third electrode 603 and the channel layer 400 may be made close to improve the response speed of the nitride-based semiconductor device 1 while increasing the response precision of the device.

Hereinafter, the operation and effects of the nitride-based semiconductor device 1 according to the embodiment of the present disclosure will be described.

The nitride-based semiconductor device 1 may minimize defect formation by the buffer layer 300, the channel layer 400, and the barrier layer 500.

Furthermore, the nitride-based semiconductor device 1 may suppress leakage current by the buffer layer 300, the channel layer 400, and the barrier layer 500.

Furthermore, the nitride-based semiconductor device 1 may suppress current leakage while allowing a small amount of current by the buffer layer 300, the channel layer 400, and the barrier layer 500, thereby reducing signal distortion in high-frequency devices.

Furthermore, the nitride-based semiconductor device 1 may increase the 2DEG formation speed by the buffer layer 300, the channel layer 400, and the barrier layer 500.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

[Explanation of reference signs]

| | |
|---|---|
| 1: nitride-based semiconductor device | |
| 100: substrate | 200: nucleation layer |
| 300: buffer layer | 400: channel layer |
| 500: barrier layer | 510: transition region |
| 520: first region | 530: second region |
| 540: third region | 601: first electrode |
| 602: second electrode | 603: third electrode |
| 700: insulating layer | |

1. A nitride-based semiconductor device, comprising:
a substrate;
a nucleation layer stacked on the substrate;
a buffer layer stacked on the nucleation layer,
a channel layer stacked on the buffer layer and configured to provide an electron transport path; and
a barrier layer stacked on the channel layer to form the electron transport path,
wherein the barrier layer includes nitrogen, gallium, aluminum, and oxygen, and
wherein a concentration of oxygen at a top of the barrier layer is less than a concentration of aluminum at the top of the barrier layer.

2. The nitride-based semiconductor device of claim 1, wherein an average of a concentration of nitrogen in the barrier layer is greater than an average of a concentration of each of gallium, aluminum, and oxygen in the barrier layer.

3. The nitride-based semiconductor device of claim 1, wherein an average of a concentration of gallium in the barrier layer is greater than an average of a concentration of each of aluminum and oxygen in the barrier layer.

4. The nitride-based semiconductor device of claim 1, wherein an average of a concentration of aluminum in the barrier layer is greater than an average of a concentration of oxygen in the barrier layer.

5. The nitride-based semiconductor device of claim 1, wherein the channel layer comprises gallium and nitrogen, and
wherein an average of a concentration of nitrogen in the barrier layer is lower than an average of a concentration of nitrogen in the channel layer.

6. The nitride-based semiconductor device of claim 1, wherein an average of a concentration of gallium in the barrier layer is lower than an average of a concentration of gallium in the channel layer.

7. The nitride-based semiconductor device of claim 1, wherein the barrier layer comprises a transition region, a first region disposed on the transition region, and a second region and a third region disposed on the first region,
wherein the transition region is stacked on the channel layer, and
wherein an average of a concentration of gallium in the transition region is greater than an average of a concentration of gallium in each of the third region, the second region, and the first region.

8. The nitride-based semiconductor device of claim 7, wherein the concentration of gallium in the transition region decreases toward the first region.

9. The nitride-based semiconductor device of claim 7, wherein a concentration of aluminum in the transition region increases toward the first region.

10. The nitride-based semiconductor device of claim 7, wherein a concentration of gallium at a top of the first region and a concentration of gallium at a bottom of the first region are less than a concentration of gallium at a central portion of the first region.

11. The nitride-based semiconductor device of claim 7, wherein the concentration of gallium in the second region increases toward the third region.

12. The nitride-based semiconductor device of claim 7, wherein a concentration of aluminum in the second region decreases toward the third region.

13. The nitride-based semiconductor device of claim 7, wherein the concentration of gallium in the third region decreases toward a top of the third region.

14. The nitride-based semiconductor device of claim 7, wherein a concentration of oxygen in the third region increases toward a top of the third region.

15. The nitride-based semiconductor device of claim 7, wherein a concentration of aluminum in the third region decreases toward a top of the third region.

16. The nitride-based semiconductor device of claim 7, wherein a concentration of gallium at the top of the second region is higher than the concentration of gallium in the first region, and
wherein the concentration of gallium at the top of the second region is less than a concentration of gallium at a bottom of the transition region.

17. The nitride-based semiconductor device of claim 7, wherein an average of a concentration of oxygen in the second region is lower than an average of a concentration of oxygen in the third region.

18. The nitride-based semiconductor device of claim 7, wherein a concentration of gallium at the top of the second region is less than a concentration of gallium at the bottom of the transition region.

19. A nitride-based semiconductor device, comprising:
a substrate;
a nucleation layer stacked on the substrate;
a buffer layer stacked on the nucleation layer;
a channel layer stacked on the buffer layer to provide an electron transport path; and
a barrier layer including nitrogen, gallium, aluminum, and oxygen, stacked on the channel layer, and configured to form a 2-dimensional electron gas,
wherein the barrier layer includes a transition region, a first region disposed on the transition region, and a second region and a third region disposed on the first region,
wherein a concentration of gallium in the second region increases toward the third region,
wherein a concentration of aluminum in the second region decreases toward the third region, and
wherein an absolute value of a concentration change rate of gallium in the second region is greater than an absolute value of a concentration change rate of aluminum in the second region.

20. A nitride-based semiconductor device, comprising:
a substrate;
a nucleation layer stacked on the substrate;
a buffer layer stacked on the nucleation layer;
a channel layer stacked on the buffer layer to provide an electron transport path; and
a barrier layer including nitrogen, gallium, aluminum, and oxygen, stacked on the channel layer, and configured to form a 2-dimensional electron gas,
wherein the barrier layer includes a transition region, a first region disposed on the transition region, and a second region and a third region disposed on the first region, and
wherein a concentration of gallium at a central portion of the first region is less than a concentration of gallium at any one of a top and a bottom of the first region.
